(19) United States
(12) Patent Application Publication
(10) Pub. No.: US 2026/0327852 A1
(43) Pub. Date: Oct. 22, 2026

(54) SINGLE CRYSTAL DIAMOND PRODUCT

(71) Applicant: Element Six Technologies Limited, Oxfordshire (GB)

(72) Inventors: Imogen Rose GULLICK, Coventry Warwickshire (GB); Joshua James TULLY, Coventry Warwickshire (GB); Mark Edward NEWTON, Coventry Warwickshire (GB)

(21) Appl. No.: 19/491,136

(22) PCT Filed: Jun. 14, 2024
(86) PCT No.: PCT/EP2024/066585

§ 371 Date: Dec. 8, 2025

(30) Foreign Application Priority Data
Jun. 16, 2023 (GB) 2309072.3

(51) Int. Cl. C30B 29/04; C25F 3/02; C30B 25/20; C30B 33/04; C30B 33/10

(52) U.S. Cl. CPC C30B 29/04; C25F 3/02; C30B 25/20; C30B 33/04; C30B 33/10

(57) ABSTRACT

A method for forming a single crystal diamond product. A diamond material is provided, which has extended defects. At least 75% of the extended defects are oriented in a defect direction substantially parallel to each other. A damage layer is formed in the diamond material, the damage layer comprising sp² bonded carbon. The damage layer is substantially parallel to the defect direction. The presence of the damage layer defines a first diamond layer and a second diamond layer either side of the damage layer. The damage layer is etched to separate the second diamond layer from first diamond layer.

### BACKGROUND

The present invention relates to a single crystal diamond product and to a method for forming the single crystal diamond product.

### INTRODUCTION

Thin (sub-micron) diamond membranes have applications in emerging optical and quantum electronic devices. However production of these thin films by conventional means is difficult.

Commercially available diamond plates currently have a thickness in the range from around 5 μm to several millimetres. To achieve this thickness, these plates are mechanically polished using a diamond abrasive. It is extremely challenging to polish any thinner than the lower limit, due to the hardness of diamond, and even at these achievable thicknesses the diamond is wedge shaped, with the thickness varying across the sample. This sample roughness and non-uniformity limits how thin the membrane can be made, ultimately resulting in a higher than desirable average membrane thickness, limiting its use for quantum applications.

Moreover, due to the extreme hardness of diamond, abrasive polishing often results in sub-surface damage to the diamond, which requires further processing steps if the material is being prepared for quantum applications. While this may not be hugely problematic for bulk diamonds, for thin membranes in e.g. photonics applications it is far from desirable, as it reduces both the strength and optical clarity of the diamond. Although this damage can be reduced using other methods such as chemically assisted polishing, it cannot be prevented entirely.

One technique used to achieve the desired sub-micron thicknesses is Reactive lon Etching (RIE). RIE is a dry etching technique that uses a chemically reactive plasma to remove material from the surface of the diamond. However, RIE is a slow process, typically etching at a rate of 10s of nm an hour. Consequently, it is only feasible for samples which have a thickness which is already in the micron range. RIE etching is essentially isotropic, meaning that the final morphology is determined by the starting surface. As a result, applying RIE to wedge-shaped polished diamond will result in a thinner surface but will not resolve the variable thickness.

Work by Parikh et. al. (Appl. Phys. Lett. 1992, 61 (26), 3124-3126) has shown that a combination of ion implantation and etching (either wet or dry) can be used to produce thin, uniform diamond membranes. This approach involves ion implantation of the diamond, to create a damaged layer within the diamond, where the ions come to rest, which is at a depth dependent on the energy used. This implantation is followed by annealing at 950° C. for 30 minutes, during which this end of range damage layer becomes graphitic in nature. This graphitic layer can then be removed using either a wet etch consisting of hot chromic-sulphuric acid, or a dry etch by annealing at 550° C. under oxygen. Both removal techniques free the thin layer of diamond above the graphitic layer. The chief advantage of this technique is that the ion implantation step creates an etch-able layer at a controlled and fixed distance beneath the surface, ensuring a membrane of uniform thickness, even if the two faces of the substrate have not been polished parallel. If a thicker or higher quality diamond layer is required, the substrate can have an additional diamond layer grown on top of it before the electrochemical etch and lift off takes place. If desired the diamond from the original substrate can then be removed by RIE etching, so that only the higher quality overgrown material remains.

Marchywka et al. (Appl. Phys. Lett. 63, 3521 (1993)) have shown that similar membranes can be achieved by using an electrochemical etch, instead of a chemical etch, to remove the graphitic layer. Here the sample was placed between platinum electrodes, spaced 2 cm apart, and immersed 1 cm deep in distilled water with sufficient chromic acid added to allow only 100 mA of current flow with 200 V applied bias. This voltage was then applied until full separation of the membrane was achieved. However, under these conditions the etch rate was extremely slow, taking 10 hours to separate a 3×3 mm membrane. This gives an approximate area etch rate of material removal of 0.9 mm² hr⁻¹.

In a following piece of work (J. Electrochem. Soc., 140, 2, (1993)) the same authors advocate specifically for the use of high resistivity media, believing that in a true bipolar arrangement this would cause a larger portion of the current to flow through the graphite layer implanted within the diamond, therefore increasing the etch rate.

In a more recent piece of work by Piracha et. al. (Nanoscale, 2016, 8, 6860) the authors implanted with 1 MeV helium, before annealing at 1300° C. The authors reported an area electrochemical etch rate of 0.25 mm² hr⁻¹ when using a solution of saturated boric acid mixed equally with deionised water. Little explanation is given for the choice of boric acid as an electrolyte. When this experiment was replicated using a 3.5×3.5 mm HPHT substrate, implanted with 2 MeV Carbon, as more fully described in the diamond sample preparation section, the rate was found to be slightly higher (0.8±0.04 mm² hr⁻¹).

In addition to producing thin membranes, such processes where implantation is followed by a lift off technique have applications for a number of diamond processing procedures. These include the fabrication of microscale suspended single crystal devices, which require structures difficult to fabricate by conventional means in diamond. Such processes are also useful in the separation of homoepitaxial CVD diamonds from their growth substrates. In particular, growth of high-quality single crystal diamond requires the use of a high-quality diamond substrate to seed its growth. However, removal of this substrate is difficult, due to the hardness of diamonds and results in loss of material. Using a lift-off technique to remove the diamond from the substrate after implantation is a promising way to mitigate this issue.

Although the implantation and lift-off technique has been investigated for many different applications, the etching process is little understood. A small number of etch solutions and electrolytes, such as boric acid, chromic acid and tap water have been used in the literature and the common factor for all these studies is the etch rate is very slow. U.S. Pat. No. 5,891,575A also describes a number of etch solutions and emphasizes that these should be used in a regime where 1-100 nA cm⁻² of current flows at 50-300 V of applied potential, indicative of very low conductivity solutions.

WO 2021/0176015 (the contents of which are incorporated by reference) describes conditions for electrochemical etching that can be used to significantly reduce etching times. This included high conductivity and particular chemistries that were found to form radical species under high potentials and improve the etching rate.

Even using improved electrochemical etching conditions, the etching time can be unpredictable. Some samples are found to etch quickly and easily, some samples take much longer.

### SUMMARY

There is a need for an improved process for producing thin diamond layers that has quicker and more consistent etching times.

According to a first aspect, there is provided a method for forming a single crystal diamond product. A diamond material is provided, which has extended defects. At least 75% of the extended defects are oriented in a defect direction substantially parallel to each other. A damage layer is formed in the diamond material, the damage layer comprising sp² bonded carbon. The damage layer is substantially parallel to the defect direction. The presence of the damage layer defines a first diamond layer and a second diamond layer either side of the damage layer. The damage layer is etched to separate the second diamond layer from first diamond layer.

The term “damage layer” is used herein to refer to a layer of carbon which has a crystallographic structure which differs from that of the surrounding diamond material. The term “layer” is used to define a region which extends substantially from one face of the diamond material to another face, as compared to forming isolated regions within the diamond material. However, it will be appreciated that there may be minor discontinuities in the layer and/or that the damage layer may not be completely exposed at the faces of the diamond material. However, in order for subsequent electrochemical etching to be effective, an active etchant species needs to access the damage layer. The damage layer is a layer of predominantly sp² bonded carbon, as compared to the sp³ bonded carbon structure of diamond.

As an option, the etching is a dry etching process.

As an alternative option, the etching processes is an electrochemical etching process. As a further option, the electrochemical etching is performed in a solution containing ions, the solution having an electrical conductivity of at least 500 μS cm⁻¹, and wherein the ions are capable of forming radicals during electrolysis. The electrochemical etching is optionally performed at a temperature selected from any of at least 50° C., at least 70° C. and at least 90° C.

As an option, the method comprises providing a first single crystal diamond substrate 5 having a major growth surface and, in a chemical vapour deposition reactor, growing single crystal diamond material on the first single crystal diamond substrate such that at least 75% of the extended defects are oriented in a defect direction substantially parallel to each other.

10 Optionally, the defect direction is in a substantially [100] direction and the damage layer is disposed substantially on a (100) plane.

As an alternative option, the defect direction is in a substantially [111] direction and the damage layer is disposed substantially on a (111) plane.

As an option, the first layer has a thickness selected from any of no more than 10 μm, no more than 5 μm, no more than 2 μm, and no more than 1 μm.

After forming the damage layer in the diamond material, the method optionally comprises polishing the edges of the diamond material.

As an option, the single crystal diamond material has a largest linear dimension selected from any of at least 6 mm, at least 8 mm, at least 10 mm, at least 15 mm and at least 20 mm.

As an option, the diamond material is doped. Examples of dopant materials include any of nitrogen, boron, phosphorus, and silicon.

As an option, the damage layer comprises graphitic material.

An optional method of forming the damage layer is to use an ion implantation process.

The method optionally further comprises attaching a support structure to a surface of the diamond material prior to the step of separating the first and second diamond layer, wherein the support structure and the means of attaching the support structure are formed from materials that are substantially inert to a solution in which the electrochemical etching occurs.

The method optionally further comprises, before etching the damage layer, overgrowing further single crystal diamond material on one or both of the first diamond layer and the second diamond layer.

According to a second aspect, there is provided a single crystal diamond product obtained by the method described above in the first aspect.

According to a third aspect, there is provided a single crystal diamond product comprising a first major surface opposing a second major surface, a largest linear dimension of the first major surface of at least 0.5 mm, and a thickness between the two major surface of no more than 10 μm. The single crystal diamond product has extended defects, wherein at least 75% of the extended defects are oriented in a defect direction substantially parallel to the first major surface.

As an option, the largest linear dimension of the first major surface is selected from any of at least 1 mm, at least 2 mm, at least 5 mm and at least 10 mm.

As an option, the thickness is selected from any of no more than 5 μm, no more than 2 μm, and no more than 1 μm.

According to a fourth aspect, there is provided a single crystal diamond product comprising a largest linear dimension of a major surface of at least 0.5 mm, a first layer of single crystal diamond comprising extended defects and having a thickness of no more than 10 μm, wherein at least 75% of the extended defects are oriented in a defect direction substantially parallel to the major surface, and a second layer of single crystal diamond overgrown on the first layer.

Optionally, the second layer comprises extended defects, wherein at least 75% of the extended defects are oriented in a defect direction substantially perpendicular to the major surface.

As an option for the third and fourth aspects, the defect direction is substantially in a direction selected from any of [100] and [111].

### BRIEF DESCRIPTION OF THE DRAWINGS

The present invention will now be described further by reference to the following figures and examples, which are in no way limiting on the scope of the claims.

FIG. 1 illustrates schematically a side elevation cross section view of a diamond material with a damage layer where the extended defects lie in a direction substantially perpendicular to the plane of the damage layer.

FIG. 2 illustrates schematically a side elevation cross section view of a diamond material with a damage layer where the extended defects lie in a direction substantially parallel to the plane of the damage layer.

FIG. 3 shows three images of diamond of FIG. 1A with increasing times of etching;

FIG. 4 is a flow diagram showing exemplary steps of a method of forming a diamond product;

FIG. 5 is a series of micrographs showing etching progress over time for two different samples;

FIG. 6 is a graph of etching progress with respect to time for samples with a damage layer substantially perpendicular to a defect direction;

FIG. 7 is a graph of etching progress with respect to time for samples with a damage layer substantially parallel to a defect direction; and

FIG. 8 shows etching rate for samples with a damage layer substantially parallel to a defect direction and samples with a damage layer substantially perpendicular to a defect direction.

### DETAILED DESCRIPTION

Growth of single crystal CVD diamond is described in, for example, WO01/96633 and WO01/96634. A single crystal diamond substrate is located in a reactor. A plasma is struck from gases that include a carbon-containing gas and carbon is deposited on the surface of the substrate. Diamond growth occurs vertically on an upper surface of the substrate, outwards from the corners of the substrate, and outwards from the side surfaces. This diamond growth will generally be homoepitaxial and single crystal, although diamond that has been grown heteroepitaxially also has a similar defect structure and is within the scope of the present disclosure.

It is important when growing single crystal CVD diamond to reduce the number of defects on the growth surface of the substrate. Extended defects in the grown single crystal CVD diamond nucleate from defects on the growth surface of the substrate, so reducing the number of defects on the growth surface of the substrate will also reduce the number of extended defects in the grown single crystal CVD diamond. The term ‘extended defects’ is used herein to refer to defects other than point defects. Examples of extended defects include dislocations, and bundles of dislocations.

The growth direction of a CVD single crystal diamond can generally be determined by analysing the extended defects structures within it. There are a range of configurations which can be present:
1) The simplest case is where the extended defects all grow largely parallel and in the direction of growth, making the growth direction clearly evident.
2) Another common case is where the extended defects fan out slowly about the growth direction, usually exhibiting some form of symmetry about the growth direction and at an angle typically less than 20°, and more typically less than 15°, and even more typically less than 10°, and most typically less than 5° about this axis. Again from a small area of the CVD diamond layer the growth direction is easily determined from the extended defects.
3) On occasion, the growth face is not itself at right angles to the local growth direction, but at some small angle away from this. Under such circumstances the extended defects may be biased towards the direction normal to the substrate surface of the growth zone in which they are found. Particularly near edges, the growth direction may vary substantially from the bulk of the layer, for example at {101} edge bevels on a substrate with a {001} major growth face. In both these instances, taken over the whole substrate the general growth direction is clearly evident from the extended defect structures, but equally evident is that the material is formed from more than one growth sector. In applications in which the direction of the extended defects is of importance, then it is generally desirable to use material from only one growth sector.

For the purposes of this specification, the direction of the dislocations is that direction which an analysis of the dislocation distribution would suggest to be the growth direction of the layer based on the above models. Typically and preferably, the direction of the dislocations within a particular growth sector will then be the mean direction of the dislocations using a vector average, and with at least 70%, more typically 80%, and even more typically 90% of the dislocations lying in a direction which is within 20°, more preferably 15°, even more preferably 10° and most preferably 5° of the mean direction.

The direction of dislocations can be determined for example by X-ray topography. Such methods do not necessarily resolve individual dislocations but may resolve dislocation bundles, generally with an intensity in part proportional to the number of dislocations in the bundle. Simple or preferably intensity weighted vector averaging is then possible from topographs imaging cross sections in the plane of the dislocation direction, with a topograph taken normal to that direction being distinct in having a pattern of points rather than lines. Where the original growth direction of a plate is known, then this is a sensible starting point from which to determine the dislocation direction.

WO 2004/027123 describes growing a single crystal CVD diamond on a substrate and creating a diamond wafer by removing a layer of single crystal CVD diamond from the grown single crystal CVD diamond in a direction substantially parallel to the growth direction. This ensures that most extended defects are disposed substantially parallel to the main plane of the second substrate and so do not appear at the growth surface of the second substrate. This ensures that if the diamond wafer is used as a substrate for further diamond growth, it has very few surface defects that can form nucleation points for extended defects for any single crystal CVD diamond grown on the diamond wafer.

The inventors have surprisingly found that the direction of the extended defects relative to the plane of a damage layer after ion implantation has an effect on the etch time and reproducibility. As described above, creation of a damage layer involves ion implantation of the diamond, to create a damaged layer within the diamond, where the ions come to rest, which is at a depth dependent on the energy used. Subsequent annealing causes the damage layer to become graphitic in nature, which can then be preferentially etched.

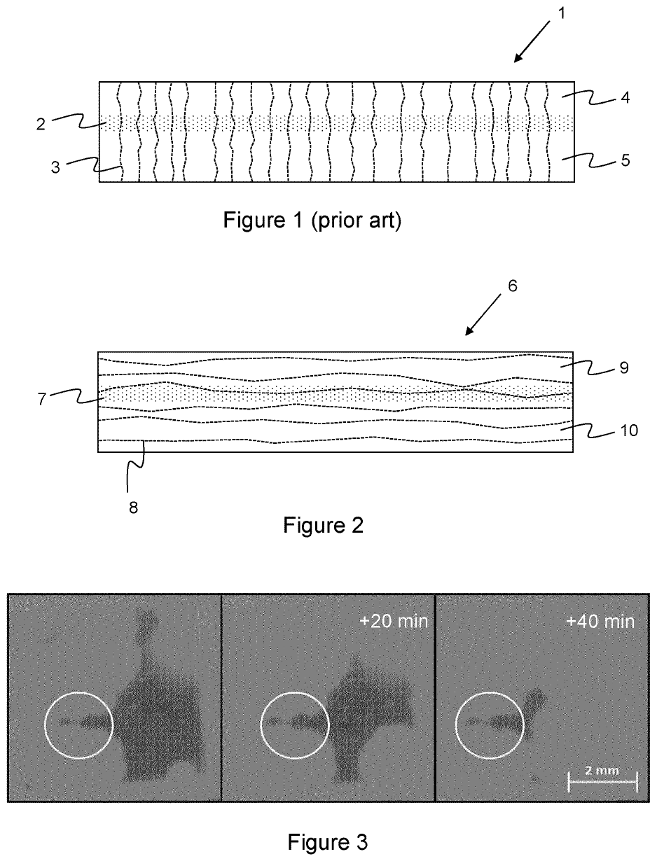

Referring to FIG. 1 herein, there is illustrated schematically a side elevation cross section view of a diamond material with a damage layer. In FIG. 1, the diamond material 1 has a damage layer 2. The extended defects 3 in the diamond material 1 lie in a direction substantially perpendicular to the plane of the damage layer 2. Subsequent annealing and etching allows the diamond material 2 to be separated into two diamond layers 4, 5. Prior art diamond has been etched in this manner, as the defect direction substantially follows the growth direction of the diamond, so larger area plates can be manufactured, and thinner plates subsequently etched and lifted off.

The ion implantation step and subsequent annealing causes graphitisation of the damage layer. As the extended defects are perpendicular to the damage layer, they intersect the damage layer at many points. Extended defects cause localised sp² bonding and disorder within the surrounding diamond crystal lattice. It was therefore previously thought that this would have either no effect or a beneficial effect when the implanted damage layer is graphitised to form more sp² carbon.

In FIG. 2, a diamond material 6 also has a damage layer 7. The extended defects 8 in the diamond material 6 lie in a direction substantially parallel to the plane of the damage layer 7. As with the example of FIG. 1A, subsequent annealing and etching allows the diamond material 6 to be separated into two diamond layers 9, 10.

Surprisingly, the inventors have found that by implanting and annealing a damage layer to lie in a plane substantially parallel to the direction of the extended defects causes the subsequent etch time of the annealed damage layer to be reliably quicker and more reproducible than that of a diamond material where the damage layer lies in a plane substantially perpendicular to the direction of the extended defects.

This is illustrated in FIG. 3, which shows a plan view of the diamond material of FIG. 1A during electrochemical etching. The darker region shows unetched graphitic material in the damage layer. In the image on the left, a substantial amount of etching has already occurred. Some graphitic material remains unetched (shown in the circle). Even after a further 20 minutes, and a further 40 minutes, some material remains unetched. This leads to difficulty in separating the layers after etching as the graphitic material that remains bonds the two diamond layers either side of the damage layer together. This phenomenon is known as ‘pinning’. Pinning is unpredictable and some samples may never be fully etched after a significant amount of time of etching, meaning the layers cannot be separated. In a commercial process, this unpredictability of etching time and etching progress is undesirable.

It has been found that pinning is greatly reduced by implanting and annealing a damage layer in a plane substantially parallel to the direction of the extended defects. Furthermore, this leads to much more predictable etching times.

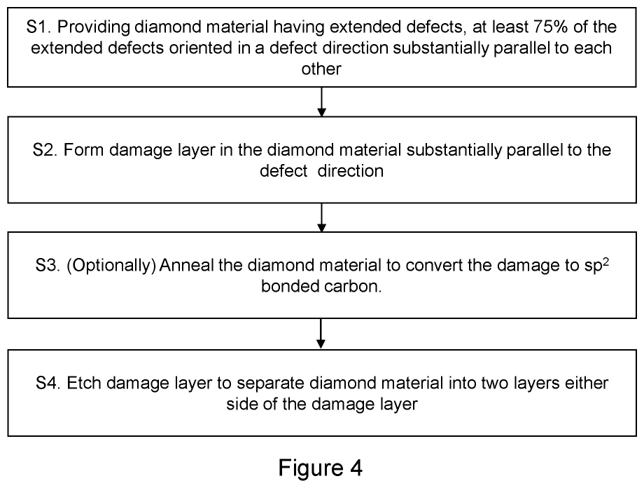

FIG. 4 is a flow diagram showing exemplary steps for a method to make a diamond product. The following numbering corresponds to that of FIG. 4:
S1. A diamond material is provided, the diamond material having extended defects. At least 75% of the extended defects are oriented in a defect direction substantially parallel to each other. This may be achieved, for example, by providing a first single crystal diamond substrate having a major growth surface and, in a chemical vapour deposition reactor, growing single crystal diamond material on the first single crystal diamond substrate such that at least 75% of the extended defects are oriented in a defect direction substantially parallel to each other. The defect direction may be in a substantially direction and the damage layer is disposed substantially on a (100) plane.
S2. A damage layer is formed in the diamond material. This is typically done by ion implantation. The damage layer is substantially parallel to the defect direction. The damage layer defines a first diamond layer and a second diamond layer on opposing sides of the damage layer.

During ion implantation, an implanted layer is formed below the surface of the diamond material. The skilled person will be familiar with ion implantation techniques. In particular, ion implantation may be effected using a high velocity ion beam. The ion beam is produced from a gaseous plasma, which comprises a mixture of ions and electrons. The ions are separated from the mixture by a small electric field and can then be accelerated and directed towards the diamond material using a stronger electric field and/or magnetic fields. The use of a strong magnetic field makes it possible to select a single ionic species for implantation. Examples of suitable ions include, but are not limited to helium, carbon, nitrogen and boron.

The depth at which the implanted layer is formed within the diamond material will depend on the energy of the ion beam used. Typically, the kinetic energies of suitable ion beams range between 1×10⁴ to about 1×10⁷ eV and this provides implanted layers at depths in the range from about 10 nm to about 5 μm. The minimum dose of ions is about 10¹⁵ ions/cm² and is typically in the range from about 10¹⁶ to about 10²⁰ ions/cm². The duration of an ion implantation step is typically in the range from 1 minute to 5 hours, more typically in the range from 2 to 10 minutes, depending on the dosage required. The current of ions and the duration of the step determine how many ions are implanted. An ion implantation step is typically performed under vacuum. Ion implantation is normally carried out between −200° C. and room temperature, although higher temperatures can be employed.

The ion implantation step creates a damage layer below the surface of the diamond material. The damage layer typically has a thickness in the range from 10 to 1000 nm, preferably in the range from 20 to 500 nm. The thickness of the damage layer can be controlled by adjusting the ion beam energy, the ion current and/or the duration of the ion implantation step.

As described above, the damage layer is a layer of carbon material which has a crystallographic structure which differs from that of the surrounding diamond material. However, it may also contain small amounts of other atoms depending on the ions used during the implantation step. Examples of other atoms which may be present in the damage layer include helium, boron, nitrogen and hydrogen.
S3. As an optional preferred step, the diamond material is annealed to convert the ion implanted damage layer to sp² bonded carbon in a process known as graphitisation. The annealing step may be carried out at a temperature in the range from 500 to 1500° C., preferably in the range from 1000 to 1400° C. The duration of the annealing step may be in the range from 0.5 to 16 hours. Annealing is performed in an inert atmosphere such as argon or nitrogen or under vacuum, for example at a pressure of less than around 1 Pa.
S4. The damage layer is etched to separate the second layer from first layer. The etching process is designed so as to not affect the diamond layers, but to preferentially remove the damage layer. The etching may be a dry etching process (such as annealing) or a wet etching process, such as electrochemical etching. For electrochemical etching, and prior to the etching step, the sides of the single crystal may be scaife polished or processed in some other way to ensure that the electrochemical etching solution has good access to the graphitic damage layer. The first layer has a thickness of no more than 10 μm. Where the other dimensions are larger this makes it difficult to handle the first layer without damaging it. To address this problem, a support structure may be attached to a surface of the diamond material If the support structure is attached prior to the step of electrochemically etching the damage layer, then the support structure and the means of attaching the support structure are formed from materials that are substantially inert to a solution in which the electrochemical etching occurs. Examples of such materials include PTFE, PEEK or glass for the support structure, and cyanoacrylate, epoxy resins, PMMA resins for any adhesive. If the support structure is attached after the etching process, then the support structure and means of attachment need not be inert to the solution in which the electrochemical etching occurs.

Prior to electrochemical etching, the diamond material containing a damage layer may be cleaned. An exemplary cleaning step is in a mixture of concentrated sulfuric acid saturated with potassium nitrate and heated to 200° C. for approximately 30 minutes. This step may then be followed by boiling for between 2 and 30 minutes in sulfuric acid, then washing with ultrapure water.

As noted above, the electrochemical etching step is performed in the presence of ions which generate, through electrolysis, etchant species which selectively etch the sp² bonded carbon of the layer formed by annealing the damage layer in the diamond material. Examples of suitable ions include any of persulfate ions, sulfate ions, oxalate ions, chloride ions, carbonate ions and metal ions. As an option, the ions may be present during the electrochemical etching at a concentration of between 0.01 M and an upper limit of the solubility of the ions in the electrolyte.

Electrochemical etching is performed in an electrochemical cell which comprises an anode, a cathode and an electrolyte. The nature of the electrochemical cell used in the electrochemical etching step is not limited and the skilled person will be familiar with suitable electrochemical cells. The anode and cathode may be formed from any conducting material. Preferably, the anode and the cathode are formed from the same conducting material. Preferred conducting materials include carbon and precious metals, such as platinum. The anode and cathode are positioned spaced apart from each other in a liquid electrolyte. A voltage is then applied between the two electrodes to create an electric field in the electrolyte. The voltage applied is typically in the range from 10 to 300 V.

The diamond material that contains a damage layer is placed in the electrolyte between the anode and the cathode in a non-contact arrangement. Preferably, it is positioned so that the faces at which the damage layer is exposed (or in closest proximity to the surface thereof) are approximately parallel to the electrodes. The sp² bonded carbon layer forms a “channel” through which the active etchant species produced as a consequence of the presence of the active ions in the electrolyte pass and, in doing so, convert the sp² bonded carbon layer to small carbon-containing molecules such as CO₂ and CH₄. Removal of the non-diamond carbon results in separation of the first diamond layer from the damage layer thus providing a diamond product as described above.

The bulk etch rate of the damage layer can be monitored using transmission microscope imaging. The progress of etching can be calculated by monitoring different colour regions, for example a MATLAB script can be used to calculate the proportion of the area that corresponds to brighter etched regions which match RGB values. This proportion is then converted to an area etched, which can then be plotted as a function of time to create etch profiles. Using this technique produces etch profiles with a time resolution of typically 1 to 10 seconds which can be used to accurately track the progress and rate of etching.

Depending on its end application, the first diamond layer may be very thin and so challenging to manipulate. However, the skilled person will be familiar with techniques for handling such thin material. For example, one approach is to float the first diamond layer off the second diamond layer in distilled water. The first diamond layer can then be floated onto a different substrate and the water under the membrane removed with a tissue, to provide a semi-permanent Van de Waals bond to the new substrate. An alternative approach is to attach the first diamond layer to a pre-grown diamond frame using an adhesive (e.g. a cyanoacrylate adhesive) and use the frame to manipulate the diamond product with a reduced risk of damage.

It is not fully understood why etching a damage layer in diamond that is substantially parallel to the extended defects orientation improves the etching time and reduces the likelihood of pinning, but the following examples show that a significant improvement to etch times and reliability is made. While not being bound by any specific theories, the inventors tentatively propose that etching rates are quickest when the damage layer comprises ordered sp² bonded material. It can be seen from FIG. 1 that when the defect direction is substantially perpendicular to the plane of the damage layer, the defects intersect the damage layer at many points. These points may give rise to disordered sp² bonding, which may be more resistant to etching than ordered sp² bonding, which would explain why pinning could occur in regions with significant numbers of extended defects. As can be seen from FIG. 2, when the defect direction is substantially parallel to the plane of the damage layer, the defects intersect the damage layer at fewer points, reducing the likelihood of pinning and making the etch rate reproducible and predictable.

### EXAMPLES

To demonstrate the invention as defined in the appended claims, a series of samples were prepared using optical grade single crystal diamond obtained from Element Six. The samples and their dimensions are provided in Table 1 below.

TABLE 1
Description of samples

| | Length 1 | Length 2 | Area | Thickness | |
|---|---|---|---|---|---|
| Sample | (mm) | (mm) | (mm²) | (μm) | Cut Direction |
| H1 | 3.5 | 3.5 | 12.25 | 300 | Perpendicular |
| H2 | 3.5 | 3.5 | 12.25 | 300 | Perpendicular |
| H3 | 3.5 | 3.5 | 12.25 | 300 | Perpendicular |
| H4 | 3.5 | 3.5 | 12.25 | 300 | Perpendicular |
| H5 | 3.5 | 3.5 | 12.25 | 300 | Perpendicular |
| H6 | 2 | 2 | 4 | 300 | Perpendicular |
| V1 | 3.75 | 3.75 | 14.0625 | 300 | Parallel |
| V2 | 3.75 | 3.75 | 14.0625 | 300 | Parallel |
| V3 | 3.75 | 3.75 | 14.0625 | 300 | Parallel |
| V4 | 3.75 | 3.75 | 14.0625 | 300 | Parallel |
| V7 | 3.75 | 3.75 | 14.0625 | 300 | Parallel |

Samples with the prefix ‘H’ all had damage layers implanted in a plane perpendicular to the direction of the extended defects, as is known in the prior art. Samples with the prefix ‘V’ all had damage layers implanted in a plane perpendicular to the direction of the extended defects. The ‘H’ samples were prepared by removing horizontal slices of 300 μm thickness from a single crystal optical grade diamond. The ‘V’ samples were prepared by removing vertical slices of 300 μm thickness from a single crystal optical grade diamond, as described in WO 2004/027123.

All of the samples were Scaife polished to obtain a smooth, damage free surface prior to implantation. Some samples were further etched using Inductively Couple Plasma Reactive Ion Etching (ICP-RIE) to remove material containing sub-surface polishing damage.

The samples were all ion implanted with 2 MeV C ions at a dose of 2×10¹⁶ cm⁻², so the depth of the peak of the implant was assumed to be 1.2 μm (according to SRIM). Taking into account the thickness of the damage layer, the resultant separated diamond layers were expected to have a thickness of approximately 750 nm.

After ion implantation, the samples were annealed in a tube furnace at 1300° C. in a nitrogen atmosphere for two hours to graphitize the damage layer. Some samples were subsequently overgrown with further diamond. Where edges were laser cut or overgrown after ion implantation, the edges of the samples were scaife polished to allow the electrochemical etch solution to access the graphitized damage layer.

Where samples are overgrown with further diamond, this is done by Chemical Vapour Deposition. The thickness of the layer of further diamond which is grown will depend on the intended end application of the diamond layer produced by the method of the invention. Where the diamond layer is intended for use in an optical application, the overgrown layer typically has a thickness in the range from a few nm to about 10 mm. Where the diamond layer produced by the method of the invention is for use in an electronic device, the overgrown layer typically has a thickness in the range from about 1 nm to about 100 μm.

CVD methods for the deposition of diamond are now well-established and have been described extensively in the patent and other literature. The method generally involves providing a source gas which, on dissociation to form plasma, can provide reactive gas species such as radicals and other reactive species. Dissociation of the source gas is brought about by an energy source such as microwaves, RF energy, a flame, a hot filament or a jet-based technique, and produces reactive gas species which are allowed to deposit onto a substrate and form diamond.

The samples were then glued to a carrier to improve handleability using a glue and a carrier inert to the electrochemical etch solution.

The samples were then pinned between two electrodes in a 50 mM H₂SO₄ solution. A 30 V DC potential difference was applied between the electrodes to effect the electrochemical etching of the damage layer until etching was complete. This was determined using a backlit microscope, such that the etched portions of the diamond transmitted light and the unetched portions did not transmit light. The unetched portions therefore appear darker.

Once the samples had been etched, the diamond layers either side of the damage layer was separated. The thinner layer was termed a membrane. There are several known techniques for lifting off membranes, such as floating them off in water. As described above, if pinning has occurred and etching is incomplete, it is extremely difficult to remove an undamaged membrane.

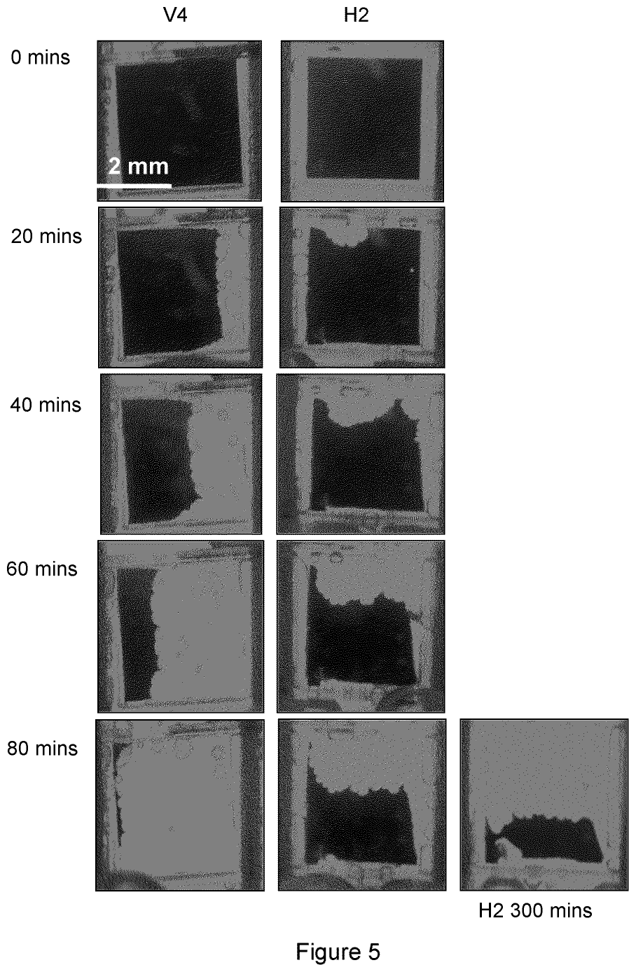

FIG. 5 is a series of micrographs showing etching progress over time for the V4 and the H2 sample. The dark areas represent unetched areas, and the lighter areas represent etched areas. Sample V4 etched smoothly from the anode to the cathode and was almost completely etched by 80 minutes. In contrast, sample H2 etched from different sides in an unpredictable way, and was around 50% etched after 80 minutes. Pinning occurred, and the sample was still not fully etched after 300 minutes.

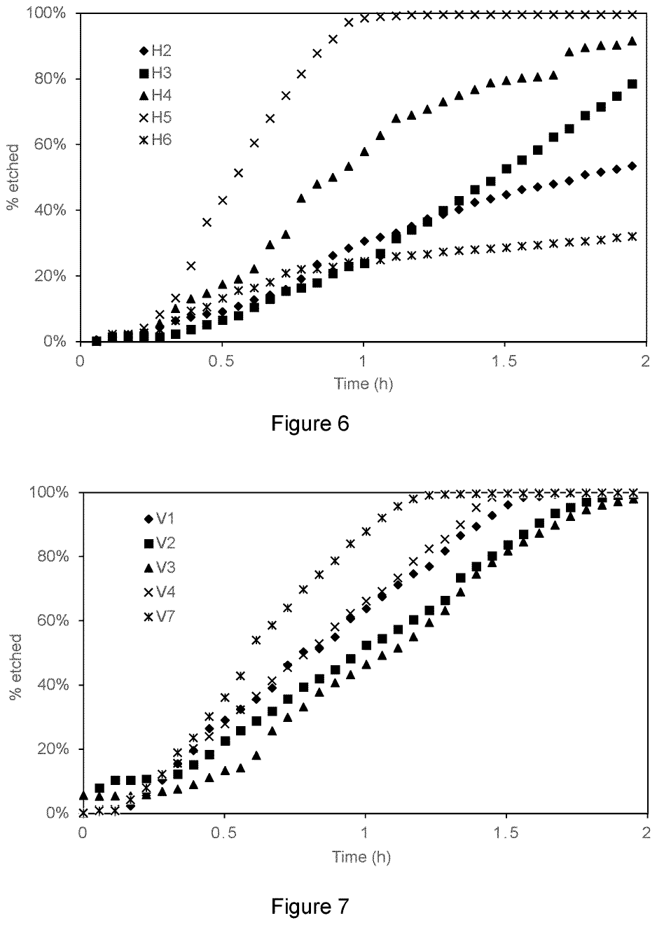

The micrographs taken from the etching of the samples were analysed to determine the percentage of the final area etched with respect to time. FIG. 6 is a graph of etching progress with respect to time for the H samples, and FIG. 7 is a graph of etching progress with respect to time for the V samples.

Of the H samples, only H5 was fully etched after 2 hours. The remaining samples either took much longer, or did not fully etch at all owing to pinning. All of the V samples were substantially fully etched after 2 hours, demonstrating the speed and reproducibility of the process. None of the V samples displayed pinning, they all etched completely.

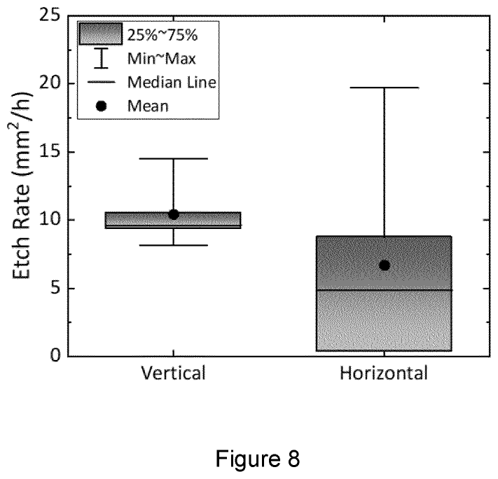

The etching rate in mm²/h was determined for the samples using the data from FIGS. 6 and 7. This is represented in FIG. 8. The V samples all etched at a mean rate of 10 mm²/h with a minimum rate of around 8 mm²/h and a maximum rate of just under 15 mm²/h. The H samples, on the other hand, etched at much more variable rates and in some cases did not completely etch at all, and had a lower mean and median etching rate than the V samples.

Creating a damage layer that is in a plane substantially parallel to the defect direction has been shown to be much more effectively and quickly etched than the known process of creating a damage layer that is in a plane substantially perpendicular to the defect direction.

While this invention has been particularly shown and described with reference to embodiments, it will be understood to those skilled in the art that various changes in form and detail may be made without departing from the scope of the invention as defined by the appendant claims.

1. A method for forming a single crystal diamond product, the method comprising:
providing a diamond material having extended defects, wherein at least 75% of the extended defects are oriented in a defect direction substantially parallel to each other;
forming a damage layer in the diamond material, the damage layer comprising sp² bonded carbon, the damage layer being substantially parallel to the defect direction, wherein the presence of the damage layer defines a first diamond layer and a second diamond layer either side of the damage layer; and
etching the damage layer to separate the second diamond layer from first diamond layer.

2. The method according to claim 1, wherein the etching is a dry etching process.

3. The method according to claim 1, wherein the etching processes is an electrochemical etching process.

4. The method according to claim 3, wherein the electrochemical etching is performed in a solution containing ions, the solution having an electrical conductivity of at least 500 μS cm⁻¹, and wherein the ions are capable of forming radicals during electrolysis.

5. The method according to claim 3, wherein the electrochemical etching is performed at a temperature selected from any of at least 50° C., at least 70° C. and at least 90° C.

6. The method according to claim 1, further comprising:
providing a first single crystal diamond substrate having a major growth surface;
in a chemical vapour deposition reactor, growing single crystal diamond material on the first single crystal diamond substrate such that at least 75% of the extended defects are oriented in a defect direction substantially parallel to each other.

7. The method according to claim 1, wherein the defect direction is in a substantially [100] direction and the damage layer is disposed substantially on a (100) plane.

8. The method according to claim 1, wherein the defect direction is in a substantially [111] direction and the damage layer is disposed substantially on a (111) plane.

9. The method according to claim 1, wherein the first layer has a thickness selected from any of no more than 10 μm, no more than 5 μm, no more than 2 μm, and no more than 1 μm.

10. The method according to claim 1, further comprising, after forming the damage layer in the diamond material, polishing the edges of the diamond material.

11. The method according to claim 1, wherein the single crystal diamond material has a largest linear dimension selected from any of at least 6 mm, at least 8 mm, at least 10 mm, at least 15 mm and at least 20 mm.

12. The method according to claim 1, wherein the diamond material is doped.

13. The method according to claim 12, wherein the diamond material is doped with any of nitrogen, boron, phosphorus, and silicon.

14. The method according to claim 1, wherein the damage layer comprises graphitic material.

15. The method according to claim 1, further comprising forming the damage layer by an ion implantation process.

16. The method according to claim 1, further comprising attaching a support structure to a surface of the diamond material prior to the step of separating the first and second diamond layer, wherein the support structure and the means of attaching the support structure are formed from materials that are substantially inert to a solution in which the electrochemical etching occurs.

17. The method according to claim 1, further comprising, before etching the damage layer, overgrowing further single crystal diamond material on one or both of the first diamond layer and the second diamond layer.

18. (canceled)

19. A single crystal diamond product comprising:
a first major surface opposing a second major surface;
a largest linear dimension of the first major surface of at least 0.5 mm;
a thickness between the two major surface of no more than 10 μm;
the single crystal diamond product having extended defects, wherein at least 75% of the extended defects are oriented in a defect direction substantially parallel to the first major surface.

20. The single crystal diamond product according to claim 19, wherein the largest linear dimension of the first major surface is selected from any of at least 1 mm, at least 2 mm, at least 5 mm and at least 10 mm.

21. (canceled)

22. A single crystal diamond product comprising:
a largest linear dimension of a major surface of at least 0.5 mm;
a first layer of single crystal diamond comprising extended defects and having a thickness of no more than 10 μm, wherein at least 75% of the extended defects are oriented in a defect direction substantially parallel to the major surface;
a second layer of single crystal diamond overgrown on the first layer.

23. (canceled)

24. (canceled)
